(19) United States
(12) Patent Application Publication
(10) Pub. No.: US 2004/0234898 A1
(43) Pub. Date: Nov. 25, 2004

(54) Magnetic flowcell systems and methods

(76) Inventors: Charles R. Batishko, Benton City, WA (US); Glen C. Dunham, Kennewick, WA (US); Lawrence E. Bowman, Fairbanks, AK (US)

Correspondence Address: WOODARD, EMHARDT, MORIARTY, MCNETT & HENRY LLP, BANK ONE CENTER/TOWER, 111 MONUMENT CIRCLE, SUITE 3700, INDIANAPOLIS, IN, 46204-5137, US

(21) Appl. No.: 10/869,557

(22) Filed: Jun. 16, 2004

Related U.S. Application Data
(63) Continuation-in-part of application No. 10/072,360, filed on Feb. 6, 2002.

(51) Int. Cl. G03F 7/00

(52) U.S. Cl. 430/312; 430/311; 430/319

(57) ABSTRACT

One embodiment of the present invention includes a flowcell with an inlet and an outlet in fluid communication with a cavity that is effective to receive a fluid flow from the inlet and to discharge at least a portion of that fluid flow through the outlet. The flowcell further includes a structure extending across the cavity to divide the fluid flow, which includes a magnetic material to capture magnetically attractable material in the fluid flow. The system further includes a sensor arranged to detect an optical property of the magnetically attractable material while captured in the cavity.

### CROSS-REFERENCE TO RELATED APPLICATIONS

The present application is a continuation-in-part of U.S. patent application Ser. No. 10/072,360 filed 6 Feb. 2002, which is hereby incorporated by reference in its entirety.

### GOVERNMENT RIGHTS

This invention was made with Government support under Contract DE-AC0676RL01830 awarded by the U.S. Department of Energy. The Government has certain rights in the invention.

### BACKGROUND OF THE INVENTION

The present invention relates to analytical devices and methods, and more particularly, but not exclusively, relates to magnetic flowcells.

There has been a growing interest in the development of flowcell technology for analyzing chemical and/or biological materials. Of particular interest has been the utilization of magnetism to control certain components of the material being analyzed. There is also a growing interest in developing cost-effective techniques to manufacture flowcell devices from commonly available materials, and at the same time decrease flowcell size. Thus, there is a demand for further contributions in this area of technology.

### SUMMARY

One embodiment of the present invention includes a unique technique for providing or using an analytical device. Other embodiments include unique methods, systems, devices, and apparatus involving flowcells.

A further embodiment includes: depositing a first layer of a photosensitive material and patterning the first layer to form one or more flowcell structures made of the photosensitive material. In one particular form, this embodiment may further include depositing a further layer of the photosensitive material and patterning this further layer to provide one or more other flowcell structures made of the photosensitive material. In one preferred form, the photosensitive material includes a photoreactive polymer. In a more preferred form, the photosensitive material includes an ultraviolet (UV)-activated photoresist. In an even more preferred form, the photosensitive material includes a UV-activated epoxy photoresist. In a most preferred form, the photosensitive material includes SU-8 photoresist. Alternatively or additionally, the photosensitive material may carry with it a magnetic substance of a paramagnetic, ferromagnetic, ferrimagnetic, and/or permanent magnet type.

Still another embodiment of the present invention includes depositing a layer of a photosensitive substance carrying a magnetic material. This layer is patterned to define one or more magnetic attracting structures made of the photosensitive substance and the magnetic material. These structures can be formed as part of a flowcell. The magnetic material may be one or more of a paramagnetic, ferromagnetic, ferrimagnetic, and/or a permanent magnet type. In one preferred form, the photosensitive substance includes an organic, photoreactive polymer. In a more preferred form, the photosensitive substance includes a UV-activated photoresist. In an even more preferred form, the photosensitive substance includes a UV-activated epoxy photoresist. In a most preferred form, the photosensitive substance includes SU-8 photoresist.

Yet another embodiment of the present invention includes: flowing a fluid through a cavity of a flowcell from an inlet to an outlet; dividing flow of the fluid through the cavity with a structure including a magnetic material; applying a magnetic field from the magnetic material to capture magnetically attractable material carried in the fluid through the cavity; and sensing an optical property of the magnetically attracted material captured by application of the magnetic field. In one form, the structure is positioned across the cavity from one surface to an opposing surface, and is located between the inlet and the outlet. The optical property may be due to electroluminescence, photoluminescence, chemiluminescence, phosphorescence, or fluorescence, to name just a few examples.

Another embodiment of the present invention includes a flowcell with a first part and a second part opposite one another that are each comprised of a different layer of a cured photoresist epoxy. The flowcell is shaped to define a cavity between these parts which is in fluid communication with an inlet and an outlet. The cavity receives a fluid flow from the inlet and discharges at least a portion of the fluid flow through the outlet. The flowcell further includes a magnetic structure inside the cavity to selectively capture magnetically attractable material in the fluid flow.

Further embodiments, forms, benefits, advantages, features, and aspects of the present invention shall become apparent from the description and drawings contained herein.

### BRIEF DESCRIPTION OF THE DRAWING

FIG. 1 is a schematic view of an analysis system.

FIG. 2 is a partial, sectional, diagrammatic side view of one type of flowcell that can be included in the system of FIG. 1.

FIG. 3 is a plan view of one stage of manufacture of the flowcell shown in FIG. 2.

FIG. 4 is a plan view of another stage of manufacture of the flowcell shown in FIG. 2.

FIG. 5 is a partial side view corresponding to the stage of flowcell manufacture shown in FIG. 4.

FIG. 6 is a plan view of a stage of manufacture of the flowcell subsequent to that depicted in FIGS. 4 and 5.

FIG. 7 is a plan view of a stage of manufacture of the flowcell after that depicted in FIG. 6.

FIG. 8 is a partial, sectional plan view of an alternative type of flowcell that can be included in the system of FIG. 1.

### DETAILED DESCRIPTION

For the purposes of promoting an understanding of the principles of the invention, reference will now be made to the embodiments illustrated in the drawings and specific language will be used to describe the same. It will, nevertheless, be understood that no limitation of the scope of the invention is thereby intended. Any alterations and further modifications in the described embodiments and any further applications of the principles of the invention as described herein are contemplated as would normally occur to one skilled in the art to which the invention relates.

One embodiment of the present application includes a flowcell that is at least partially fabricated from a photosensitive substance. This fabrication may include photolithographic patterning of one or more layers of the substance. In one form, a portion of the flowcell is made of the photosensitive substance that carries with it a magnetic material. As used herein, a “magnetic material” broadly includes paramagnetic, ferromagnetic, ferrimagnetic, and permanent magnet materials, to name a few examples. Further embodiments include one or more flowcells provided in a single device and systems incorporating one or more flowcells.

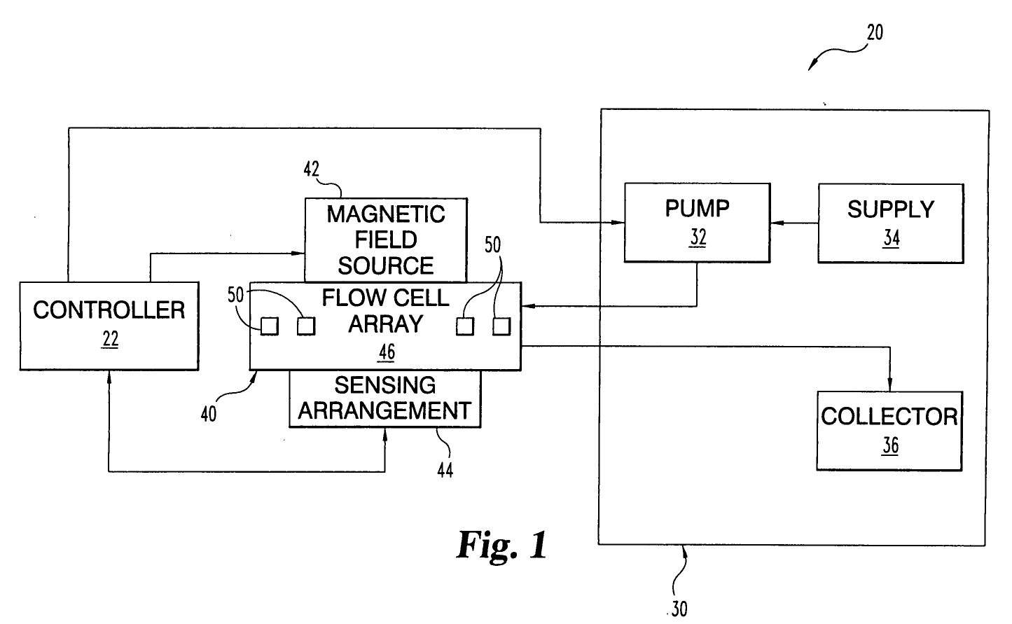

For example, FIG. 1 illustrates analysis system 20. System 20 includes controller 22, fluid management subsystem 30, and flowcell subsystem 40. Controller 22 is operatively coupled to fluid management subsystem 30 and flowcell subsystem 40. Controller 22 directs various operations of subsystems 30 and 40, and processes/stores data provided to controller 22 from subsystem 40 as will be more fully explained hereinafter.

Controller 22 can be of an analog type, a digital type, or a combination of these; and can be comprised of one or more components. Controller 22 may be a software or firmware programmable processor, a dedicated hardware configuration—such as a state logic machine, or a combination of both programmable and dedicated hardware. Furthermore, controller 22 can include one or more independently operable processing constituents, such as Arithmetic-Logic Units (ALUs), Computer Processing Units (CPUs), and the like. For a form of controller 22 with multiple processing constituents, distributed, pipelined and/or parallel processing can be utilized, as appropriate. In one particular embodiment, controller 22 is a type of digitally programmable, highly integrated, signal processor. In other embodiments, controller 22 is of a general purpose processor type or such other arrangement as would occur to those skilled in the art.

Typically, controller 22 includes one or more types of memory (not shown). Memory included in controller 22 can be variously configured as would occur to those skilled in the art. Such memory may include one or more types of solid-state electronic memory, magnetic memory, optical memory, of either a volatile and/or nonvolatile variety. Furthermore, this memory can be integral with one or more other components of controller 22 and/or comprised of one or more distinct components. For instance, this memory can be at least partially integrated with a processor, that collectively constitute controller 22. Furthermore, this memory can include removable devices such as a floppy disc, cartridge, or tape form of removable electromagnetic recording media; an optical disc, such as a CD or DVD type; an electrically reprogrammable solid-state type of nonvolatile memory such as a smart card or chip; and/or such different variety as would occur to those skilled in the art.

In one embodiment, memory is utilized to load and/or store a portion of the operating logic for controller 22. Such operating logic can be in the form of program instructions for a programmable type of controller 22, which controller 22 executes to perform one or more desired procedures, operations, and/or routines. In other embodiments, some or all of this operating logic is defined by dedicated hardware of controller 22. It should be appreciated that controller 22 can include interfaces for receiving input from an operator and/or providing output perceivable by an operator. Also, controller 22 can include other communication interfaces, such as a computer network interface, and/or different interfaces as would occur to those skilled in the art. Controller 22 can include one or more signal conditioners/filters to filter and condition signals as desired; one or more format converters, such as analog-to-digital (A/D) and/or Digital-to-Analog (D/A) converter types; and/or one or more oscillators, control clocks, interfaces, ports, limiters, power supplies, or other types of component/devices as would occur to those skilled in the art to implement the various embodiments of the present inventions.

Fluid management subsystem 30 includes pump 32, fluid supply 34, and fluid collector 36. Pump 32 is responsive to control signals from controller 22 to selectively provide fluid from supply 34 to flowcell subsystem 40 as desired. Collector 36 receives fluid from flowcell subsystem 40 after discharge therefrom. Fluid management subsystem 40 can include standard conduits, valves, regulators, and/or other fluidic structures to implement the present invention, which are not shown to preserve clarity.

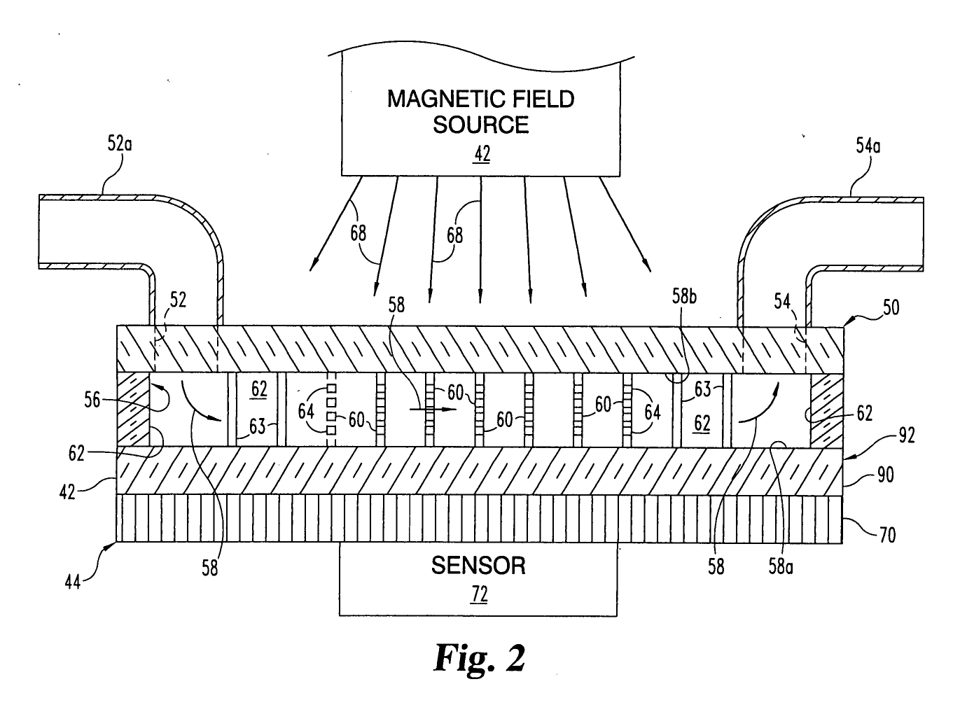

Flowcell subsystem 40 includes magnetic field source 42, sensing arrangement 44 and flowcell array 46. Flowcell array 46 includes a number of flowcells 50, a few of which are schematically shown in FIG. 1, and one of which is illustrated in detail in FIG. 2. Referring additionally to FIG. 2, flowcell 50 includes fluid inlet 52 coupled to conduit 52a and outlet 54 coupled to conduit 54a. Inlet 52 and outlet 54 are in fluid communication with flowcell cavity 56. Flowcell cavity 56 is bounded by lower surface 58a and upper surface 58b. Lower surface 58a and upper surface 58b are opposite one another, are each generally planar, and are approximately parallel to one another in the depicted embodiment. Inside cavity 56 are a number of magnetic structures 60 extend from lower surface 58a to upper surface 58b, which are each generally in the shape of a pillar or column. Cavity 56 is also bounded by surrounding walls 62 as illustrated in FIG. 2. Several support columns 63 are also illustrated in FIG. 2, which are generally positioned at opposing end portions of flowcell 50, with magnetic structures 60 positioned therebetween.

Structures 60 include magnetic material 64 that is responsive to a magnetic field. Material 64 is schematically represented in structures 60, as designated by the like reference numeral in FIG. 2. In one embodiment, magnetic material 64 is of a ferromagnetic type, such as nickel, iron, cobalt or certain metallic compounds or alloys or including such chemical elements. In other embodiments, magnetic material 64 of structure 60 may be differently comprised. Further aspects regarding the composition of structures 60 for certain embodiments are described in connection with one mode of manufacturing flowcell 50, which is illustrated through FIGS. 3-7. As illustrated, support columns 63 do not include magnetic material 64; however, in other embodiments, one or more of support columns 63 can include magnetic material 64. In still other embodiments, more or fewer structures 60 and/or columns 63 are utilized with none, some, or all including magnetic material 64.

During use, flowcell 50 receives a flowing fluid from inlet 52 via conduit 52a that progressively passes through cavity 56 in the direction indicated by arrows 58. At least a portion of this fluid can be discharged through outlet 54 via conduit 54a. The flow can be initiated, stopped, and otherwise controlled by pump 32 of fluid management subsystem 30 and/or one or more other components of subsystems 30 and 40 in response to control signals from controller 22. Magnetic field source 42 is responsive to signals from controller 22 to selectively apply a magnetic field to array 46. Arrows, a few of which are designated by reference numeral 68, schematically represent such a magnetic field. Application of this magnetic field can be selective to a subset of flowcells 50 or applicable to all. Source 42 can be in the form of one or more electromagnets responsive to controller 22, one or more permanent magnets that move in response to control signals from controller 22 to selectively apply a magnetic field to one or more designated flowcells, or a combination of these, just to name a few examples. When this magnetic field is applied to a given flowcell 50, it is oriented to cause and/or enhance magnetic attraction of a magnetically attractable substance in the fluid to structure 60 via magnetic material 64, the application of which will be more fully explained hereinafter.

Sensing arrangement 44 detects one or more optical properties of material in cavity 56 for each of the flowcells 50. Signals corresponding to such properties are provided to controller 22 for further processing and/or storage as desired. Typically, an emission of light by an electroluminescent, photoluminescent, chemiluminescent, phosphorescent, and/or fluorescent mechanism is sensed with arrangement 44 in the infrared, visible, and/or ultraviolet light ranges. As depicted in FIG. 2, arrangement 54 includes a fiberoptic plate in the form of substrate 70 that is in optical communication with cavity 56, and sensor 72 in optical communication with substrate 70. In one form, sensor 72 is of a Charge-Coupled Device (CCD) type. Alternatively or additionally, one or more photodiodes, photoresistors, and/or photomultiplier tubes could be utilized for sensing, just to name a few examples.

Referring generally to FIGS. 1 and 2, one mode of operation of system 20 is next described. First, a sample that potentially includes one or more substances of interest is prepared. A substance of interest may include, for example, a chemical agent, such as a nerve toxin, or biological material, such as Anthrax. During sample preparation, any substance(s) of interest in the sample are coupled or bonded to or other associated with a molecule that is appropriately selective to such substance to assist in identifying such substance(s). For the depicted embodiment that includes a photosensing-based form of arrangement 44, this molecule includes a photodetectable property that is useful in indicating the presence of the substance(s) of interest in the sample. For instance, an electroluminescent, photoluminescent, chemiluminescent, phosphorescent, and/or fluorescent light emission of the compound changes, is suppressed, or is initiated by the presence of the substance(s) of interest in a detectable manner.

The sample is further prepared for analysis by coupling a magnetic bead, particle, or other magnetically attractable constituent to it. The resulting compound is typically a liquid or is carried in a liquid, slurry fluid, and/or fine particle fluid. These preparation operations are performed using standard techniques such as those described in U.S. Pat. Nos. 5,798,083 to Massey et al.; U.S. Pat. Nos. 6,303,316 to Kiel et al., and U.S. Pat. Nos. 6,623,984 to Fleischman et al., all of which are hereby incorporated by reference.

Once prepared, the resulting fluid sample, that potentially includes one or more substances of interest, can be represented as the fluid of supply 34 depicted in FIG. 1. Fluid from supply 34 is provided under pressure to flowcell subsystem 40 by pump 32 as controlled by controller 22. This fluid is provided from subsystem 30 to one or more flowcells 50 of array 46 through one or more corresponding inlets 52. Fluid received by each flowcell 50 passes through the corresponding cavity 56 and is discharged through the corresponding outlet 54. Fluid discharge by any flowcells 50 is collected by standard fluidic structures and provided to collector 36. It should be appreciated that supply 34 and collector 36 can be the same, such that the fluid recirculates between subsystems 30 and 40. Alternatively or additionally, multiple supplies and/or collectors for different fluid compositions could be utilized, such that different flowcells 50 of array 46 can receive the different compositions to provide a form of “parallel” analysis thereof. As a further addition or alternative, different flowcells 50 may have different properties such that different properties of the same fluid composition are evaluated by these different flowcells 50 in parallel. In other embodiments, at least some of flowcells 50 of array 46 are coupled in series such that the outlet 54 of at least one flowcell 50 is connected to the inlet 52 of another to provide for a “pipeline” analysis of various aspects of the fluid. In still another embodiment, only a single flowcell 50 is utilized in system 20 instead of array 46.

During the flow of fluid through flowcells 50 of array 46, a magnetic field from source 42 is applied to one or more flowcells 50 to cause structure 60 to magnetically attract and capture magnetic material as it flows with the fluid, including any substance(s) of interest prepared in the manner previously explained. This captured material can then be interrogated using sensing arrangement 44 to provide corresponding data to controller 22 for storage and/or further processing. It should be appreciated that the sensor interrogation can be performed on magnetically trapped material in cavity 56 as fluid continues therethrough, and/or after stopping fluid flow. Further, while a fluid flow is stopped, the magnetic field from source 42 can be removed to cease magnetic capture provided that the material does not otherwise migrate through flowcell 50. It should also be appreciated that the detection of an undesirable material such as a nerve agent or Anthrax (for example), that occurs during interrogation, can be used to direct different handling procedures of such material. Once detected, the magnetic capture aspects of flowcell 50 can be utilized to essentially filter and remove the threatening agents. Furthermore, monitoring of a given environment for one or more threatening agents; such as the air or water of an office building, government facility, or other forum; can be implemented with system 20 through continuous and/or scheduled evaluation with flowcells 50. If such agent(s) are detected, magnetic capture and/or chemical selectivity can be utilized to facilitate filtering/removal.

In yet other embodiments, it should be appreciated that optical sensing and/or magnetic capture may be absent. In some of these alternatives, different techniques may be used for interrogation and/or handling of materials in flowcell 50. For example, an application utilizing an organic semiconductor can include electrodes for interrogation. In still other examples, pulsed fluid flow may be utilized with or without magnetic capture to provide for a controlled interrogation. In yet further embodiments, the flowcells may receive fluid but not discharge it, in lieu of magnetic capture. For other embodiments, structure 60 may be comprised of a magnetic material providing sufficient capture capability without application of an external field and be of a type desired to retain the captured material once attracted without a controlled mechanism of release.

Turning to FIGS. 3-7, one process for manufacturing flowcell 50 is next described; where like reference numerals refer to like features. This process includes several photolithographic patterning stages of a photosensitive polymeric material that can be cured to provide suitable structural members/parts of flowcell 50 in the partially constructed form of workpiece 76.

The manufacturing process begins with the selection, cleaning, and other preparation operations (as needed) of fiberoptic plate 70. Fiberoptic plate 70 serves as substrate 74 for workpiece 76. Referring to FIG. 3, a photosensitive material is deposited on substrate 74 to provide photosensitive layer 78. In FIG. 3, the partial cutaway view in the lower left corner of workpiece 76 shows a portion of substrate 74 beneath layer 78. In other embodiments, a different substrate transparent to one or more light wavelengths of interest can be used in lieu of fiberoptic plate 70. Additionally or alternatively, optical interrogation can be performed through a transparent cover on top of the device and/or through a transparent wall on a side of the device. In one particular form, a top covering formed of a photosensitive epoxy is selected that is also transparent to the one or more light wavelengths of interest, such as SU-8. Nonetheless, in other embodiments, a different transparent material could be used in lieu of or in addition to photosensitive epoxy.

Photosensitive layer 78 is photolithographically patterned using standard techniques. For example, as shown in FIG. 3, photolithographic patterning equipment 80 is utilized to apply mask 82 that selectively exposes regions of photosensitive layer 78 to light of a type to which photosensitive layer 78 is responsive. Alternatively or additionally, patterning of a suitably comprised layer 78 can be performed by performing selective election beam exposure in a standard manner. Mask feature 84 illustrates a representative example of an exposed region 86 of photosensitive layer 78 that has been defined with mask 82 of equipment 80.

Generally, selective processing of layer 78 is carried out by first providing layer 78 comprised of a photosensitive material, applying an external stimulus to the layer to create voids in the first layer, and removing any material present in those voids. This external stimulus may be in the form of light and/or electrons to name a couple of nonlimiting examples. It should be appreciated that the creation of voids may be “positive” or “negative”, depending upon the type of photosensitive material selected. For example, and not meant to be limiting, for certain embodiments, UV light activates the photosensitive material, causing the hardening of an epoxy material. The surrounding non-hardened material may then be removed by a selective solvent or the like. In contrast, and again not meant to be limiting, when patterning photosensitive materials with electron beams, it is more typical that the portion of the photosensitive materials which have been exposed to the electron beams have bonds broken, which facilitates selective removal of such exposed regions to form voids. The present application is directed broadly to photosensitive materials that are used in either a positive or negative exposure scenario.

While not meant to be limiting, preferred photosensitive materials include an organic, photoreactive polymer. In more preferred embodiments, the photosensitive material includes UV-activated photoresists, which can include both a resin and a curing agent. Suitable types of such resins include, but are not limited to bisphenol A glycidyl ether polymer (CAS 28906-96-9) (CAS 25068-38-6), p-tertbutylphenyl glycidyl ether (CAS 3101-60-8), polyester, urethane, or combinations thereof. Suitable curing agents corresponding to such resins include, but are not limited to mixed triarylsulfonium/hexafluoroantimonate salt (CAS 89452-37-9/CAS 71449-78-0), 2-Hydroxy-4′-hydroxyethoxy-2-methylpropiophenone (CAS 106797-53-9), phenylbis(2,4,6-trimethyl benzoyl) phosphine oxide (CAS 162881-26-7), 1-hydroxycyclohexyl phenyl ketone (CAS 947-19-3), Bis(2,6-dimethoxybenzoyl)-2,4,4 trimethylpentylphosphineoxide (CAS 145052-34-2), 2,4,6 trimethylbenzophenone (CAS 954-16-5), 4-methylbenzophenone (CAS 134-84-9), 2-methylbenzophenone (CAS 131-58-8), 2,2-diethoxyacetophenone (CAS 6175-45-7), and combinations thereof. In an even more preferred embodiment, the photosensitive material includes a UV-activated, epoxy photoresist. A most preferred embodiment of the photosensitive material includes commercially available SU-8 resin/curing agent combinations available from MicroChem Corp. of Newton, Mass.). This embodiment includes an epoxy resin of bisphenol A glycidyl ether polymer (CAS 28906-96-9), and a photoacid generator curing agent of mixed triarylsulfonium/hexafluoroantimonate salt (CAS 89452-37-9/CAS 71449-78-0). Solvents for this embodiment includes propylene carbonate (CAS 108-32-7), gammabutyrolactone (CAS 96-48-0), and cyclopentanone. For embodiments utilizing the SU-8 composition, activation by ultraviolet light causes exposed regions to form covalent cross-links, hardening the epoxy-based polymer.

Again, while not meant to be limiting, other more preferred forms of the present invention utilize photosensitive materials that include electron beam-activated resists, such as AZ5200-novolak type, ZEP7000 an acrylate and styrene copolymer (both available from Nippon Zeon Co. Ltd., Tokyo, Japan); polymethylmethacrylates such as 495PMMA and 950PMMA—(both available from MicroChem Corp. of Newton, Mass.); UV-cured adhesives and potting agents, such as CT-523-LV (an epoxy: Bisphenol A diglycidyl ether polymer) (CAS 25068-38-6) and p-tertbutylphenyl glycidyl ether (CAS 3101-60-8) available from the Resin Technology Group, South Easton, Mass.); UV-cured conformal coatings, such as 1A37HV and 1C61 (epoxies--HumiSeal Corp., Woodside, N.Y.); UV-cured powder coatings, such as those based on resins such as Uracross P3898—a vinylether urethane resin, Uracross P3307—a vinylether urethane resin, and Uracross P3125—a polyester resin (DSM Resins, Zwolle, The Netherlands) and photoinitators, such as Irgacure 2959 (2-Hydroxy-4′-hydroxyethoxy-2-methylpropiophenone CAS 106797-53-9), Irgacure 819 (phosphine oxide, phenylbis(2,4,6-trimethyl benzoyl)-CAS 162881-26-7), Irgacure 184 (1-hydroxycyclohexyl phenyl ketone CAS 947-19-3), Irgacure 1800 (Bis(2,6-dimethoxybenzoyl)-2,4,4 trimethylpentylphosphineoxide, CAS 145052-34-2), Ciba Geigy), and Esacure TZT (2,4,6-trimethylbenzophenone CAS 954-16-5, 2-methylbenzophenone CAS 131-58-8 and 4-methylbenzophenone CAS 134-84-9, Sartomer Corp) and 2,2-diethoxyacetophenone (CAS 6175-45-7) and combinations thereof.

After activation, any further curing operations are applied, as desired. For an embodiment utilizing SU-8, a thermocuring operation is typically applied after exposure to the activating UV light. Following any curing operations, development of the patterned layer 78 takes place. During development, portions of the photosensitive layer 78 are removed in accordance with the desired pattern. For the mask-patterned approach illustrated (which corresponds to an embodiment utilizing UV-activated SU-8 for layer 78), unexposed regions are removed. In other embodiments, depending on the composition of the photosensitive layer 78, and/or manner of exposure activation; exposed regions or unexposed regions are removed, corresponding to a positive exposure process or a negative exposure process, respectively. For the example illustrated, exposed region 86 corresponds to mask feature 84 which is retained, while unexposed region 88 is removed during development. Likewise, for SU-8 applications, a positive exposure technique is typically applied, in which unexposed regions are washed away with an appropriate solvent. After selective layer removal of unexposed region 88, the remaining exposed region 86 provides flowcell structure 90 that serves as base part 92 (see FIG. 2). Part 92 defines lower surface 58a of flowcell 50 as initially depicted in FIG. 2.

The flowcell manufacturing process continues by depositing another photosensitive layer 94 on workpiece 76, which covers structure 90. After deposition, layer 94 is patterned; where such patterning includes: exposing selected regions of layer 94 to an appropriate form of light by masking, curing the exposed layer as needed, and developing the exposed layer 94 to remove any region so designated by the mask pattern. As previously explained in connection with layer 78, layer 94 can alternatively or additionally be patterned using other techniques with layer 94 being of a correspondingly suitable composition.

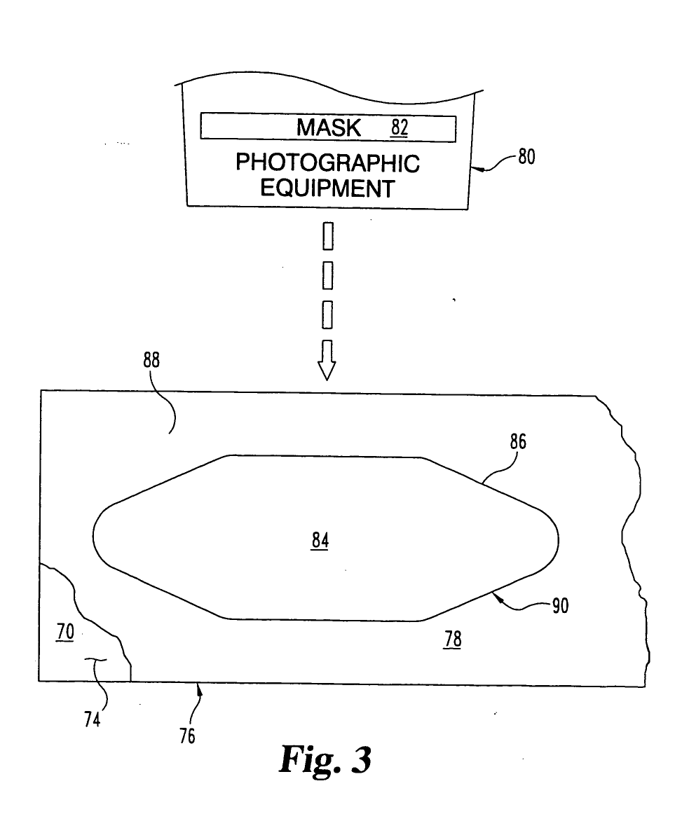

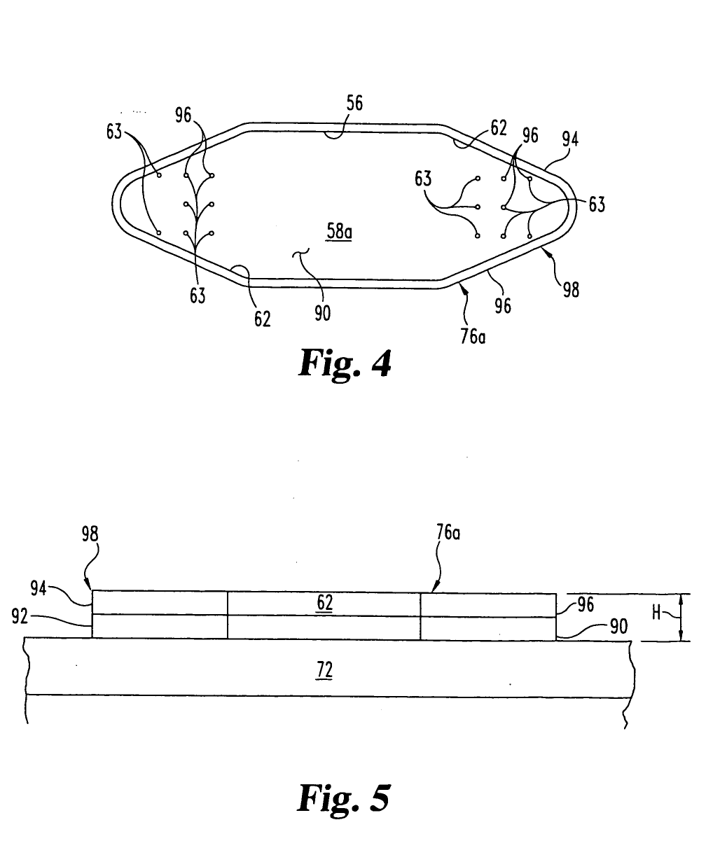

FIGS. 4 and 5 provide a top plan view and a side view, respectively, of a partially assembled flowcell workpiece 76a, after patterning of layer 94 to provide further flowcell features 96, only a few of which are specifically designated by reference numerals to preserve clarity. As illustrated therein, features 96 include walls 62 previously described in connection with FIG. 2 and columns 63. Walls 62 and columns 63 are joined to base part 92 to provide a stacked arrangement, from which cavity 56 takes shape. Walls 62 of features 96 enclosed cavity 56, providing a form of spacer part 98 of workpiece 76a.

After forming features 96 from layer 94, a further layer 100 is deposited inside cavity 56 to at least partially fill it. Layer 100 includes a photosensitive material, such as that comprising layer 78 and 94. Furthermore, layer 100 also includes magnetic material 64 that is combined with the photosensitive material. Magnetic material 64 is the same as that previously described in connection with FIG. 2. In one preferred embodiment, magnetic material 64 is mixed in a photoresist material that is deposited to provide layer 100. In a more preferred embodiment, magnetic material 64 is of a ferromagnetic type such as iron or nickel, that is generally uniformly mixed with an SU-8 form of photosensitive material in such proportions that the desired structural integrity of the cured layer is maintained, while at the same time providing a desired level of magnetic attraction force with the magnetic material 64 included therein. In other forms, magnetic material 64 may not be uniformly dispersed or mixed throughout the photosensitive material and/or may vary in type or distribution as would occur to those skilled in the art. In one other preferred embodiment of the present invention, the magnetic material includes a ferromagnetic substance. A more preferred embodiment of magnetic material of a ferromagnetic type includes nickel or iron. Other preferred embodiments include a paramagnetic or ferrimagnetic type of magnetic material, and/or a permanent magnet material, such as ALNICO I-VIII, and rare earth magnets including, but not limited to, those having samarium, cobalt, neodymium-iron-boron, and combinations thereof.

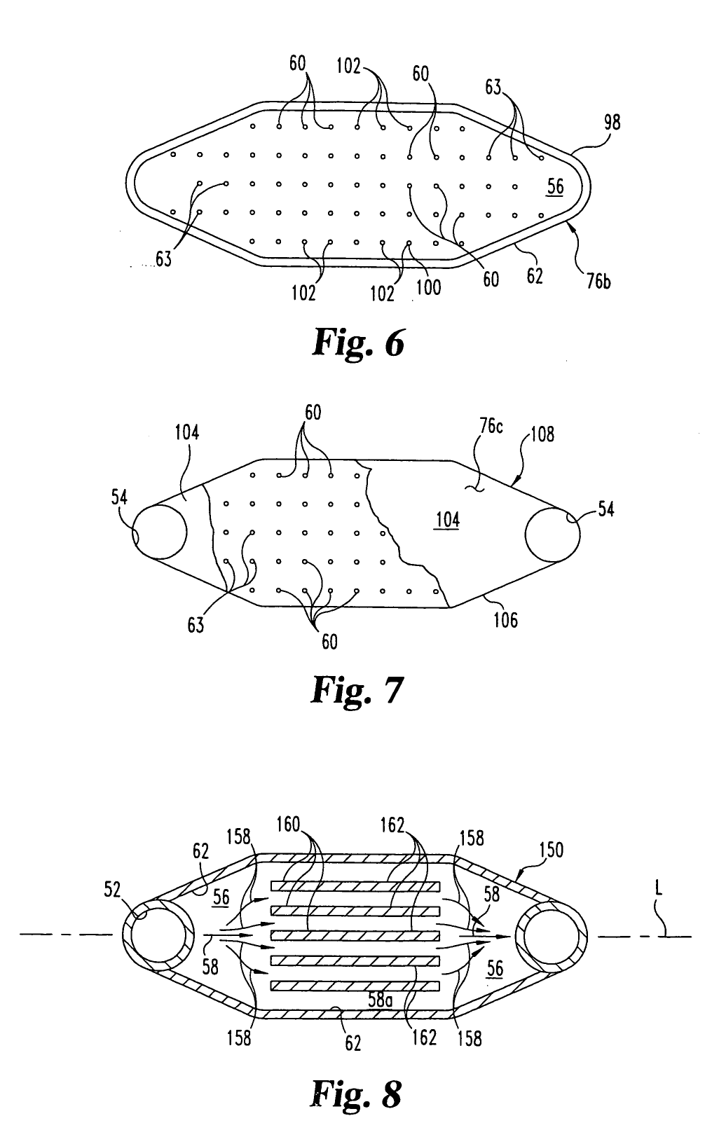

After depositing layer 100, it is patterned in any of the manners previously described to result in the formation of features 102 after development, as shown in partially assembled flowcell workpiece 76b of FIG. 6. Notably, features 102 include magnetic material 64 together with the resulting polymer structure from the cured and developed photosensitive material. Features 102 are the same as those previously designated as magnetic structures 60 and have the form of a post, pillar, and/or column within cavity 56. Structures 60 are positioned for placement in the flow stream that passes through cavity 56 during use, as previously described in connection with FIGS. 1 and 2. Only a few of features 102 are designated with reference numerals in FIG. 6 to preserve clarity.

Referring to FIG. 7, after formation of features 102, a sacrificial material (not shown) is deposited in cavity 56, such that a generally planar surface is defined at or above the height of structures 60, walls 62, and columns 63. This height is diagrammatically represented as height “H” in FIG. 5. An additional photosensitive layer 104 is then deposited on this surface, covering the sacrificial material. Layer 104 is comprised of a photosensitive material like that used in layer 78, 94 and/or 100. Correspondingly, it is patterned to provide feature 106 that serves as cap part 108 of flowcell 50 of workpiece 76c in FIG. 7. Cap part 108 is of generally the same shape and size as base part 92, and defines upper surface 58a that bounds cavity 56. As further shown by the partial cut-away view in FIG. 7, inlet 52 and outlet 54 are formed through cap part 108, using standard techniques. It is through inlet 52 and/or outlet 54 that the sacrificial material remaining in cavity 56 can be removed with an appropriate solvent.

It should be appreciated that the sacrificial material at least partially fills the voids between walls 62, substantially conforming to structures 60 and columns 63 located within cavity 56. Correspondingly, the sacrificial material lends greater structural support for the formation of layer 104 then would structures 60, walls 62, and columns 62 in its absence. Also, without the sacrificial material, layer 104 would likely undesirably fill cavity 56, so that the patterning of layers 94 and/or 100 would be undesirably affected, potential resulting in damage or loss to the pattern. The sacrificial material is preferably selected as a material soluble in one or more of: YY liquid carbon dioxide; supercritical carbon dioxide; hydrofluoroethers, such as HFE-7100 (methyl nonafluoroisobutylether CAS 163702-08-7 and methyl nonafluorobutylether CAS 163702-07-6) and HFE-7200 (ethyl perfluoroisobutyl ether CAS 163702-06-5 and ethyl perfluorobutyl ether CAS 163702-05-4) available from 3M Corp, Minneapolis, Minn., fluorocarbons, such as FC-75 (perfluorocarbons CAS 86508-42-1) available from 3M Corp, Minneapolis, Minn., and alkanes, such as hexane or other petroleum distillates. Preferred sacrificial materials thus include, but are not limited to, fluoropolymers, such as perfluro N-octyl methacrylate and perflurocyclohexyl acrylate, hydrocarbon waxes (paraffins), fluorocarbon waxes, and combinations thereof.

After removal of the sacrificial material, formation of flowcell 50 can be completed, including the coupling of conduits 52a and 54a, source 42, sensor 72, and the like as represented in FIG. 2. In other embodiments, a different arrangement as would occur to those skilled in the art may be utilized. In one particular example, a fiberoptic plate serves as a substrate that is approximately 3 mm thick. An absorbing thin film is placed on the fiberoptic plate. On the fiberoptic plate, a base part is made from SU-8 having a thickness of approximately 100 microns. Stacked on this base, walls and support columns are formed from SU-8 also having a thickness of approximately 100 microns. Furthermore, magnetic structures are formed from a mixture of SU-8 and ferromagnetic powder. The magnetic structures were placed on approximately a 1 mm center-to-center grid in the flowcell cavity for this arrangement. An SU-8 cap was formed, also having a thickness of about 100 microns. The diameters of the inlet and outlet for this arrangement were about 2 mm each. Corresponding total capture area of the flowcell was about 5 mm square.

It should be appreciated that several cells can be manufactured at the same time using the process described in connection with FIGS. 3-7. Further, in other embodiments, one or more flowcells may not include a magnetic structure 60 and/or may include more or fewer layers made from a photosensitive material. In yet other alternatives, the magnetic structures may vary from one cell to the next or within a cell as to size, shape, quantity, and/or composition.

FIG. 8 presents a top plan, sectional view of flowcell 150; where like reference numerals refer to like features. Flowcell 150 can be manufactured in the same manner as described in connection with FIGS. 3-7, except magnetic structures 160 are shaped differently than structures 60—being in the form of longitudinal walls 162 instead, and columns 63 are absent. Walls 162 have a longitudinal axis L approximately parallel to the direction of flow of fluid through cavity 56 as represented by arrows 58, and extend across cavity 56 from one opposing surface to the other (surface 58b is not shown due to the sectional nature of FIG. 8). Further, FIG. 8 illustrates that walls 162 serve as flow dividers as represented by arrows 158. Likewise, structures 60 of flowcell 50 provide for the local division of fluid flow thereabout when operated in the manner previously described in connection with FIGS. 1 and 2.

The method of the present invention may be further extended through the use of other materials that are mixed with, or adhered to, the photosensitive materials, and thereby impart a desired property to the resultant structure. For example, strength-enhancing additives such as glass and/or carbon fibers, or dopants designed to alter the physical properties of the photosensitive materials, including, without limitation, the thermal, optical, acoustic, or elastic modulus may be added. Other materials can be adhered to the surface of cured photoresist features. For example, organic molecules having high affinity for selected bio-molecules and the like can be adhered to the surfaces of flowcells made in accordance with the previously described embodiments of the present invention to impart specific surface chemistries to such devices, or certain surfaces of such devices.

### EXPERIMENTAL EXAMPLES

The following are nonlimiting experimental examples of the present invention and are in no way intended to limit the scope of any aspect of the present invention.

### First Example

A series of experiments were conducted to demonstrate the principles of the present invention. These experiments demonstrated the fabrication of devices from photosensitive material, that included closed tunnels or conduits. In one example, a device was prepared with a conduit 150 microns wide, 50 microns tall, and 10,000 microns long, as illustrated in U.S. patent application Ser. No. 10/072,360.

Photolithographic processing was carried out using a commercially available photosensitive material and solvent system, specifically SU-8-50C from Microchem Corporation of Newton, Mass., which is a specific form of SU-8 previously described;.where the “50” denotes viscosity, which ranges from 5 to 500 in Microchem's arbitrary labeling, and the “C” represents an alternative solvent chosen for lower toxicity but which is also less polar than the standard solvent provided by the company.

Typical substrates were 50 millimeter diameter recycled silicon wafers about 0.014″ thick, one side polished, with occasional minor scratches as a consequence of the recycling. Doping of the wafers varied. The wafers were prepared by wiping with methanol, rinsing with deionized water, etching briefly in buffered hydrofluoric acid, rinsing with deionized water, blowing dry with nitrogen, and baking on a hotplate at 250 degrees Celsius (C) for 30 minutes.

The wafer was placed on a spinner after removal from the hotplate and brief cooling. Bubble-free SU-8-50C was dispensed from an autopipette onto the center of the stationary wafer (2.5 mL for a 50 mm wafer). Spinning with high acceleration to 2000 rpm was started as soon as possible after the dispense and continued for 90 seconds. The film was dried before patterning by a gentle hotplate bake starting at 35 degrees C. and ramping to 65 degrees C. at 1 degree C. per minute, then cooled back to 35 degrees C. at 2 degrees C. per minute.

Patterning was accomplished by selectively exposing the SU-8 coated wafer with ultraviolet light through a mask. SU-8 is a negative photosensitive material, meaning the material exposed to UV-light cross-links to make it less soluble. A glass mask coated with an opaque iron oxide film in the negative image was placed over the SU-8 coated wafer in a contact mask aligner, and exposed to UV-light from a high pressure mercury vapor lamp for about 100 seconds.

After exposure, a high temperature bake was required to facilitate the cross-linking. This post-exposure bake was conducted on a hotplate ramped from 40 degrees C. to 100 degrees C. and back to 60 degrees C., all at 1 degree C. per minute. Developing (i.e. dissolving the unreacted SU-8) occurred in full strength SU-8 developer from Microchem in three successive baths. The first bath was magnetically stirred and the wafer was soaked with stirring for 6 minutes. The next two baths, with clean developer, were not stirred and the wafer soaked one minute in each. After withdrawal from the third bath, the wafer was blown dry with nitrogen.

The next step was powder-coating the wafers with a sacrificial material. For these experiments, a fluoropolymer powder was selected as the sacrificial material. The apparatus used to apply the sacrificial material was a model C-30 powder coater (Electrostatic Technologies, Inc. of Branford, Conn.). Nitrogen was used to fluidize the bed, and the electrostatic potential was set at 50 kV. The back side of each wafer was covered with static dissipative tape to keep powder off of the back of the wafer. The wafer was held using vacuum applied through a small suction cup (as is used for positioning integrated circuits). A copper tube and a wire provided a path to electrical ground as the wafer was coated.

Held thusly, each wafer was passed through the powder cloud about one inch above the bed. Residence time in the powder cloud was about three seconds. The tape was removed from the wafer, and the wafer was placed in a cold oven. The oven was then ramped to 100 degrees C. over about ten minutes, and the wafers were held at this temperature overnight. The oven was turned off the next morning and allowed to cool for about one hour. This treatment left a smooth film of fluoropolymer on the wafer that completely filled and encapsulated the SU-8 microstructure.

Planarization of the fluoropolymer to the level of the SU-8 required polishing on fine sandpaper. Suitable conditions were 600 grit paper on an Ecomet 4 Variable Speed Polisher, 200 rpm wet, counter-rotating platen, and two pounds force per wafer. Wafers were attached to the polishing platen with Crystolite, which melts at about 100 degrees C. and is acetone soluble. The duration of the polishing was about five minutes.

After planarization, the wafers were removed from the platen, washed in acetone and deionized water, blown dry, and remounted on the spinner. Dispensing, spinning, baking, exposing, and developing the SU-8-50C was performed the same as above to create the second layer. The low polarity solvent of the “C” formulation was adequate to provide a desired uniform coating on the fluoropolymer. Powder coating and polishing may also be repeated as above, allowing a multilayer monolithic complex structure.

The sacrificial fluoropolymer was removed from the wafer by extraction with supercritical carbon dioxide modified with ten percent HFE-7100 (3M Corp. Minneapolis, Minn.). Wafers were placed one or two at a time in a one liter autoclave (Autoclave Engineers) equipped with a Magnedrive II.TM. stirring unit having a two inch diameter, four-bladed impeller. The Magnedrive was cooled with water at 10 degrees C. (ca. ½ gal/min) and air cooled with a fan. Wafers were suspended in the autoclave using custom made mounts. 100 mL of HFE-7100 was added to the autoclave. The autoclave was then sealed and pressurized with about 500 g of carbon dioxide. The autoclave was heated to 75 degrees C., pressurized with carbon dioxide to about 3,500 psi, and stirred at about 900 rpm for ten hours. During this time, about 500 g of carbon dioxide was slowly flowed through the autoclave (ca 0.2 mL/min).

Heating was discontinued and the autoclave was allowed to cool to ambient temperature. At this point carbon dioxide in the autoclave was a liquid, and about 600 mL of liquid carbon dioxide was drained from autoclave bottom connection. The autoclave was then heated to 75 degrees C. and pressurized with carbon dioxide to about 3,500 psi. The pressure was slowly vented overnight with the temperature maintained at 75 degrees C. Heating was discontinued once the autoclave was depressurized, and the autoclave was opened after it cooled to ambient temperature. The samples were removed and examined with optical and electron microscopy.

The sacrificial fluoropolymer powder, poly (perfluoro-n-octyl methacrylate), was prepared from monomer perfluoro-n-octyl methacrylate via a free radical initiation reaction in carbon dioxide solvent. The synthesis proper is similar to that reported by De Simone et al. in “Synthesis of Fluoropolymers in Supercritical Carbon Dioxide” , J. M. De Simone, Zihibin Guan, C. S. Elsbernd Science, 257 945-947 (1992), the entire contents of which are incorporated herein by this reference. 400 g of the monomer along with 4 g of AIBN was added to a one liter autoclave (Autoclave Engineers) equipped with a Magnedrive stirrer. The AIBN was recrystalized twice from methanol immediately prior to the reaction. The autoclave was sealed and purged three times with carbon dioxide at about 300 psi to remove atmospheric oxygen. The autoclave was heated to 60 degrees C., pressurized with carbon dioxide to about 3,000 psi and stirred for three days. The pressure was maintained with a syringe pump.

Residual initiator was extracted from the reaction mixture after cooling to room temperature. The contents of the autoclave were split into a gaseous headspace over a solution of polymer in liquid carbon dioxide. The residual initiator was extracted using a mixture of methanol/water (50/50). The methanol/water was added, the autoclave was vigorously stirred, then allowed to stand. The methanol/water separated as a layer above the liquid carbon dioxide-polymer solution. The methanol/water was drawn off through a connection at the top of the vessel. This sequence of “add, stir, settle, remove” was repeated three times with the water content increasing with each repetition such that the last cycle utilized pure water. The polymer was then collected through the bottom connection of the one liter autoclave in a stepwise fashion. Ten mL of liquid at a time was discharged into a 300 mL autoclave where the polymer precipitated and the carbon dioxide vapor was allowed to escape.

The collected fluoropolymer was ground to a powder having a particle size between 45 and 105 microns. Films of the fluoropolymer were cast by melt fusing on non-stick pie pans in an oven at 100 degrees C. Films were broken into flakes and coarse ground with a mortar and pestle using dry ice to ensure crystalinity of the fluoropolymer during grinding. Fine grinding was done with coffee grinders which were pre-chilled with dry ice. Ground fluoropolymer was sieved with precision sieves (Humbolt Scientific) until it passed through a 105 micron sieve. Sufficient fluoropolymer powder was prepared in this manner to load the powder coater (about one-half pound).

### Second Example

In a second experimental example, flowcells were fabricated from the SU-8 photoresist. Each layer of the flowcell was made by spincoating SU-8 on a substrate, exposing it to UV light through a mask, thermal curing, and washing away the unexposed photoresist (developing). First, the base and walls were fabricating using this technique in correspondence to parts 92 and 98. Powdered ferromagnetic material (nickel and iron) were mixed with SU-8, spincoated, selectively exposed by masking, and developed to create fixed locations (corresponding to structures 60) within the cell cavity where it was desired to magnetically capture magnetic material from a flow stream. The flowcell was completed by attaching a cover in the form of a small glass plate with two 0.050 inch diameter holes drilled through it to provide access points for an inlet and an outlet. The cover plate was glued in place with a UV-cured epoxy based adhesive (Resin Technology Group CT-523-LV).

Fluidic connection to the cell was made with 1/16″ outer diameter, 0.035″ inner diameter stainless steel tubing. A seal between the tubing and the flowcell cover was made by o-ring compression. The end of the tube proximal to the flowcell was threaded (0-80) to allow a pair of nuts to be locked against each other at an adjustable location. This provided a backstop for the o-ring with adjustable compression. The o-ring (silicone rubber, dash 003) was glued in place on the tube with RTV sealant. To aid the formation of a seal, a trace of grease (Dow-Corning high vacuum) was applied to the face of the o-ring which contacted the glass cover. A pair of nuts were also used to fasten the stainless steel line to a small angle fabricated from polyvinylchloride (PVC). In conjunction with a single clamp fabricated from two small aluminum bars and two machine screws, the PVC angle provided a convenient means to compress the o-ring against the flowcell cover and clamp it in place.

By connecting 1/16″ inner diameter vinyl tubing to the inlet and outlet tubes, plumbing connections were provided to flow solutions through the cell. A mixture of DALM (Diazoluminomelanin) particles in buffered saline water (phosphate buffered saline, Sigma catalog 1000-3) was prepared. The concentration of DALM was just enough to visually detect turbidity in the buffered saline solution (ca. 2 drops of DALM concentrate per liter of buffered saline).

A buret was used to deliver an adjustable flow of DALM solution to the flowcell. Heat shrink tubing was used to connect the tip of the buret to the vinyl tubing. Placing a SmCo magnet (block) immediately under the flowcell provided the necessary magnetic field (ca. 0.27 Tesla=270 Gauss, at the wetted surface) to capture and hold DALM particles at flow rates up to about 2 mL/min.

Images illustrating a sequence of capture, accumulation, and release of the DALM particles were obtained. For this arrangement, the magnetic structures are generally columnar similar to those represented as structures 60 in FIGS. 2, 6, and 7.

### Third Example

Another cell was fabricated from SU-8 photoresist using longitudinal walls rather than columns to provide magnetic structures within a cavity of the flowcell. The preparation utilized the same process to form the base and walls as described in the Second Example. After preparation, this flowcell was tested by introducing DALM particles, capturing such particles after flowing ca 20 mL of solution through the cell and release of the DALM particles upon removal of an external magnet.

Any theory, mechanism of operation, proof, or finding stated herein is meant to further enhance understanding of the present invention and is not intended to make the present invention in any way dependent upon such theory, mechanism of operation, proof, or finding. All publications, patents, and patent applications cited herein are hereby incorporated by reference, each in its entirety. While the invention has been illustrated and described in detail in the drawings and foregoing description, the same is to be considered as illustrative and not restrictive in character, it being understood that only the selected embodiments have been shown and described and that all changes, modifications and equivalents that come within the spirit of the invention as defined herein or by the following claims are desired to be protected.

What is claimed is:

1. A method, comprising:
depositing a first layer of a photosensitive material to form one or more flowcell devices;
patterning the first layer to provide one or more flowcell structures made of the photosensitive material;
depositing a second layer of the photosensitive material on the one or more flowcell structures;
patterning the second layer to provide one or more other flowcell structures made of the photosensitive material; and
completing formation of the one or more flowcell devices.

2. The method of claim 1, wherein the photosensitive material is in the form of an ultraviolet-activated, epoxy photoresist, and said patterning the first layer includes:
applying a mask to the first layer;
photolithographically applying ultraviolet light to a portion of the first layer left exposed by the mask; and
removing a portion of the first layer covered by the mask.

3. The method of claim 2, wherein the photosensitive material includes a UV-activated, epoxy photoresist in the first layer and the second layer, and the second layer further includes a magnetic material carried with the photoresist.

4. The method of claim 3, wherein the magnetic material is ferromagnetic.

5. The method of claim 1, which includes before said completing:
depositing a third layer of the photosensitive material over the one or more flowcell structures and the one or more other flowcell structures; and
patterning the third layer to provide one or more further flowcell structures made of the photosensitive material.

6. The method of claim 5, wherein one of the one or more flowcell structures provides a first part of one of the one or more flowcell devices, one of the one or more other flowcell structures provides a second part of the one of the one or more flowcell devices opposite the first part, the first part and the second part defining a cavity therebetween, and one of the one or more further flowcell structures provides a third part of the one of the one or more flowcell devices positioned to provide at least a portion of a wall bounding the cavity between the first part and the second part.

7. The method of claim 6, wherein the one of the one or more flowcell devices includes a fiber optic plate coupled to the first part and at least one sensor to detect light within the cavity.

8. The method of claim 1, wherein the one or more other flowcell structures patterned from the second layer define at least one wall portion bounding a cavity, and further comprising:
depositing a photosensitive substance in the cavity, the photosensitive substance including a magnetic material; and patterning the photosensitive substance after said depositing;
removing a portion of the photosensitive substance in accordance with said patterning to form a number of magnetic attracting structures within the cavity.

9. The method of claim 8, which includes depositing a sacrificial material in the cavity before depositing the second layer.

10. A method, comprising:
depositing a layer of a photosensitive material carrying a magnetic material;
patterning the layer to define one or more magnetic structures made of the photosensitive material and the magnetic material; and
forming a flowcell that includes the one or more magnetic structures.

11. The method of claim 10, wherein the magnetic material is ferromagnetic.

12. The method of claim 10, which includes mixing the magnetic material with the photosensitive material before said depositing.

13. The method of claim 10, wherein the photosensitive material includes a UV-activated, epoxy photoresist.

14. The method of claim 13, wherein said forming includes:
depositing one or more other layers of the photoresist without the magnetic material; and patterning the one or more other layers to make the flowcell.

15. The method of claim 10, wherein said forming includes:
defining a cavity in fluid communication with an inlet and an outlet; and
the one or more magnetic structures number at least two and are spaced apart from one another inside the cavity.

16. The method of claim 15, wherein the cavity is bounded by a first surface spaced apart form a second surface opposite the first surface, and the magnetic structures extend across the cavity from the first surface to the second surface, the magnetic structures each being operable to divide a fluid flowing from the inlet to the outlet through the cavity.

17. The method of claim 16, wherein the magnetic structures selectively capture magnetically attractable material from the fluid flowing from the inlet to the outlet through the cavity in response to application of a magnetic field generated with a device outside the cavity.

18. The method of claim 15, wherein the magnetic structures are each shaped to provide a wall with a longitudinal axis approximately parallel to a direction of flow of fluid from the inlet to the outlet.

19. The method of claim 15, wherein the magnetic structures are each in the form of a column.

20. A method, comprising:
flowing a fluid through a cavity of a flowcell from an inlet to an outlet;
during said flowing, dividing flow of the fluid through the cavity with a structure positioned across the cavity between the inlet and the outlet, at least a portion of the structure being comprised of a magnetic material;
applying a magnetic field from the magnetic material to capture magnetically attractable material carried in the fluid through the cavity; and
while in the cavity, sensing an optical property of the magnetically attractable material captured by said applying.

21. The method of claim 20, wherein the flowcell is comprised of multiple layers of UV-activated epoxy photoresist.

22. The method of claim 21, wherein the structure is comprised of one of the layers of the ultraviolet-activated epoxy photoresist that further includes the magnetic material.

23. The method of claim 20, wherein the structure is one of several spaced-apart structures at least partially comprised of the magnetic material.

24. The method of claim 23, wherein the structure is in the form of a wall with a longitudinal axis approximately parallel to a direction of flow of the fluid through the flowcell during said flowing.

25. The method of claim 20, wherein the magnetic material is ferromagnetic.

26. The method of claim 20, wherein the cavity is defined by a first approximately planar surface spaced apart form a second approximately planar surface, and the structure extends from the first surface to the second surface.

27. The method of claim 20, wherein said sensing is performed with a fiber optic plate and a charge-coupled device, and the optical property includes emission of light in at least one of the infrared, visible, and ultraviolet spectra.

28. The method of claim 20, which includes removing the magnetic field to release the magnetically attractable material from the cavity of the flowcell.

29. The method of claim 20, wherein said applying is performed with a magnet outside the cavity.

30. An apparatus, comprising: a flowcell including a first part and a second part opposite one another and each comprised of a different layer of ultraviolet-activated epoxy photoresist, the flowcell being shaped to define a cavity between the first part and the second part, the cavity being in fluid communication with an inlet and an outlet; the cavity being effective to receive a fluid flow for analysis from the inlet and discharge at least a portion of the fluid flow through the outlet, the further including a structure inside the cavity to selectively capture magnetically attractable material in the fluid flow.

31. The apparatus of claim 30, wherein the photoresist includes SU-8.

32. The apparatus of claim 30, wherein the structure is comprised of the photoresist and at least one of a paramagnetic material, a ferromagnetic material, a ferrimagnetic material, and a permanent magnet material.

33. The apparatus of claim 30, wherein the first part and the second part are approximately planar and the structure extends from the first part to the second part.

34. The apparatus of claim 30, wherein the structure is one of several spaced apart structures including a magnetic material to selectively capture the magnetically attractable material in the fluid flow.

35. The apparatus of claim 34, wherein the structures are each in the shape of a longitudinal wall operable to divide the fluid flow within the cavity.

36. A system, comprising:
a flowcell including an inlet ad an outlet in fluid communication with a cavity, the cavity being effective to receive a fluid flow from the inlet and to discharge at least a portion of the fluid flow through the outlet, the flowcell further including a structure extending across the cavity to divide the fluid flow in the cavity, the structure including a magnetic material to capture magnetically attractable material in the fluid flow; and
a sensor arranged to detect an optical property of the magnetically attractable material while captured in the cavity.

37. The system of claim 36, further comprising a magnet external to the cavity to selectively apply a magnetic field to the structure to cause the capture of the magnetically attractable material.

38. The system of claim 36, further comprising a fiber optic plate in optical communication with the cavity and the sensor and wherein the sensor is in the form of a charge-coupled device, operable to detect the optical property as an emission of light.

39. The system of claim 38, wherein the flowcell is comprised of several layers of an ultraviolet-activated, epoxy photoresist, a first one of the layers being spaced apart from a second one of the layers to define the cavity, the structure is one of several spaced apart structures inside the cavity extending from the first one of the layers to the second one of the layers, the structures are each comprised of the photoresist mixed with the magnetic material, and a third one of the layers defines at least one wall bounding the cavity between the first one of the layers and the second one of the layers.
